(19) United States
(12) Patent Application Publication
(10) Pub. No.: US 2012/0104207 A1
(43) Pub. Date: May 3, 2012

(54) TEST BRACKET FOR CIRCUIT BOARD

(75) Inventors: SHANG-YANG HSIEH, Tu-Cheng (TW); JUN-YANG FENG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/944,767

(22) Filed: Nov. 12, 2010

(30) Foreign Application Priority Data
Oct. 28, 2010 (CN) 201010523095.7

(51) Int. Cl. H05K 7/14

(52) U.S. Cl. 248/298.1

(57) ABSTRACT

A test bracket includes a base board and two position poles. The position poles are perpendicularly and slidably mounted on the base board opposing each other. Each position pole defines a groove opposing the other position pole. A distance between the position poles is adjusted through sliding the position poles on the base board along the slots. The position poles hold a circuit board to be perpendicularly mounted on the base board by receiving the circuit board in the grooves.

### BACKGROUND

1. Technical Field

The present disclosure relates to a test bracket for testing circuit boards.

2. Description of Related Art

Circuit boards are widely used in electronic devices, such as motherboards in computer systems. Before shipment, the circuit boards need to be tested, a common method to test circuit boards may include two steps. First, a circuit board is put on an insulation board for the testing of the first side of the circuit board. Second, after testing the first side of the circuit board, the circuit board is turned over and put on the insulation board, so that the second side can be tested. However, when the circuit board is turned, elements of the circuit board may be damaged, and further, this method is time consuming.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is an exploded, isometric view of an embodiment of a test bracket.

FIG. 2 is an enlarged view of a circled portion II of FIG. 1.

FIG. 3 is an assembled, isometric view of the test bracket of FIG. 1.

FIG. 4 is a schematic view of a circuit board being placed on the test bracket of FIG. 3.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

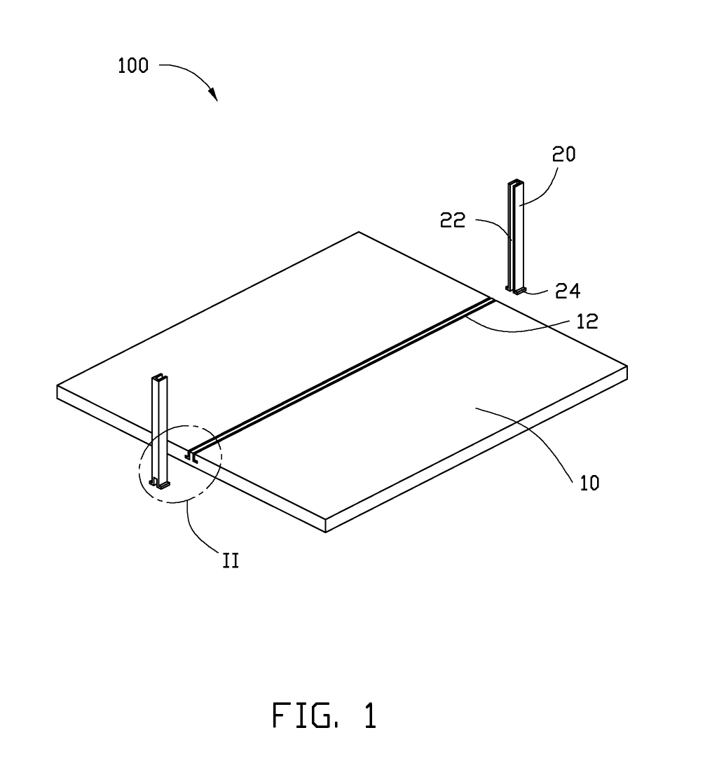

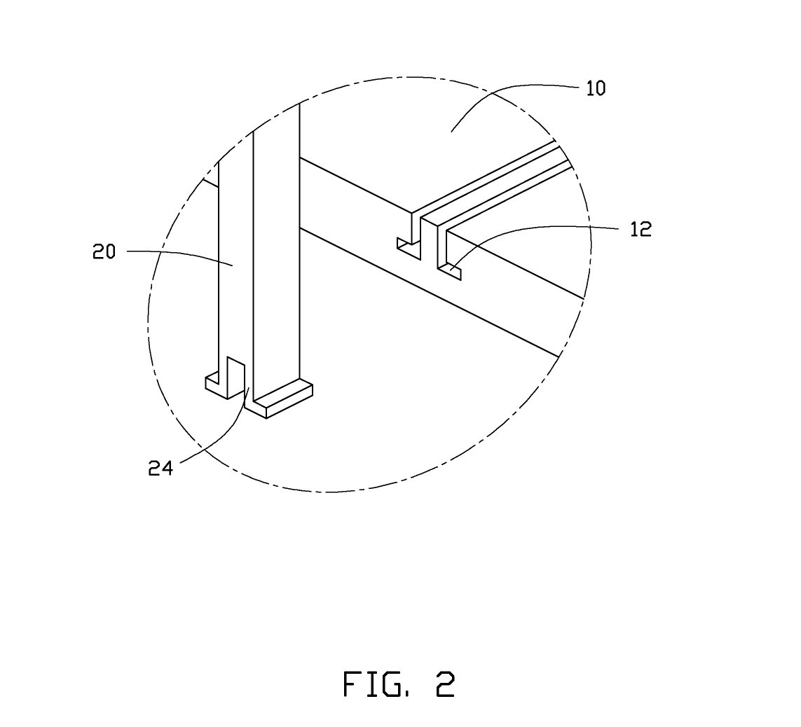

Referring to FIGS. 1 and 2, an embodiment of a test bracket 100 includes a base board 10 and two position poles 20. In one embodiment, the base board 10 and the position poles 20 are made of insulating material, such as wood or plastic.

The base board 10 is substantially rectangular-shaped. The base board 10 defines two substantially parallel slots 12 in the middle. Each slot 12 is substantially L-shaped in cross section and extends through opposite sides of the base board 10.

Each position pole 20 is a long rectangular frame. The position pole 20 defines a groove 22 in a side of the position pole 20 from the top end to the bottom end of the position pole 20, therefore the position pole 20 is substantially U-shaped in cross section. Two substantially L-shaped sliding portions 24 respectively extend from opposite sidewalls of the groove 22, corresponding to the slots 12 of the base board 10.

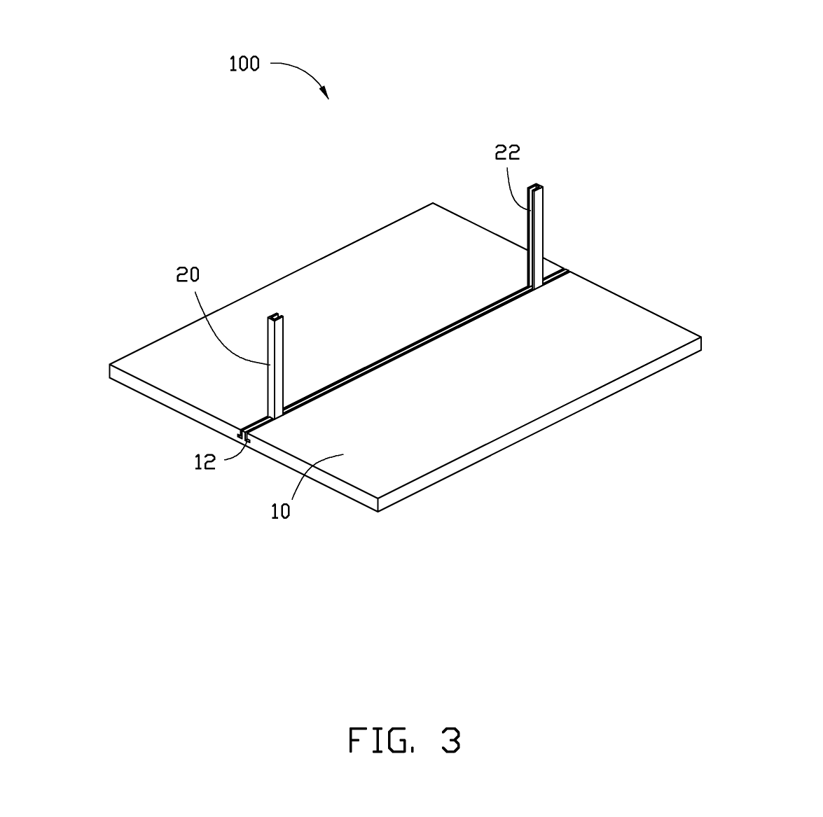

Referring to FIG. 3, in assembly, the sliding portions 24 of each position pole 20 are inserted into the corresponding slots 12 of the base board 10, and the grooves 22 of the position poles 20 face each other. At this time, the position poles 20 can be slid along the slots 12 of the base board 10. Namely, the distance between the position poles 20 can be adjusted by sliding the position poles 20 on the base board 10 along the slots 12.

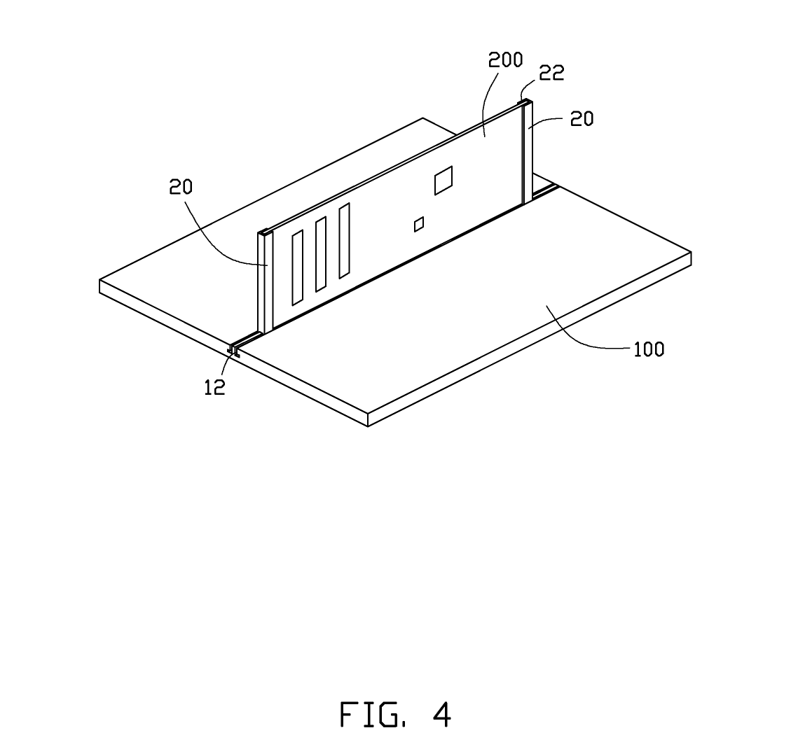

Referring to FIG. 4, in using the test bracket 100 to test a circuit board 200, the distance between the position poles 20 is adjusted to match a length of the circuit board 200. Opposite ends of the circuit board 200 are inserted in the grooves 22 of the position poles 20, therefore the circuit board 200 is perpendicularly fixed on the base board 10 with the position poles 20. Opposite side surfaces of the circuit board 200 can be tested without turning over the circuit board 200, which can save time and protect elements of the circuit board 200 being damaged.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A test bracket for testing a circuit board, comprising:
a base board; and
two position poles perpendicularly and slidably mounted on the base board, each position pole defining a groove facing the other position pole; wherein a distance between the position poles is adjusted through sliding the position poles on the base board;
wherein the position poles are operable to hold a circuit board to be perpendicularly mounted on the base board through opposite ends of the circuit board received in the grooves.

2. The test bracket of claim 1, wherein the base board defines two parallel slots in the middle of the base board, the slots are substantially L-shaped in cross section, each of the position poles is a rectangular frame and the corresponding groove is defined in the position pole from a top end to a bottom end, thereby the position pole is substantially U-shaped in cross section, two substantially L-shaped sliding portions extends from bottom ends of opposite sidewalls of the position pole bounding the groove, the position poles are mounted on the base board through the sliding portions of the position poles being inserted into the slots of the base board.

3. The test bracket of claim 1, wherein the base board and the position poles are made of insulating material.
